(19) United States
(12) Patent Application Publication
(10) Pub. No.: US 2010/0019327 A1
(43) Pub. Date: Jan. 28, 2010

(54) Semiconductor Device and Method of Fabricating the Same

(76) Inventor: Eun Jong SHIN, Seoul (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/177,824

(22) Filed: Jul. 22, 2008

(51) Int. Cl. H01L 21/8238; H01L 27/092

(52) U.S. Cl. 257/377; 438/218; 257/E27.062; 257/E21.632

(57) ABSTRACT

Disclosed are a semiconductor device and a method of fabricating the same. The semiconductor device includes a semiconductor substrate having first and second active areas defined thereon by isolation layers, a first gate electrode in the first active area, in which the first gate electrode includes a first silicide, and a second gate electrode in the second active area, in which the second gate electrode includes a second silicide having a composition ratio of silicon different from a composition ratio of silicon of the first silicide.

The present application claims priority under 35 U.S.C. 119 to Korean Patent Application No. 10-2007-0073779 (filed on Jul. 24, 2007), which is hereby incorporated by reference in its entirety.

### BACKGROUND

Generally, a MOS transistor includes a source/drain area formed on a semiconductor substrate, and an oxide layer and a gate poly layer formed on the semiconductor substrate having the source/drain area.

The MOS transistor may be classified into an NMOS transistor and a PMOS transistor according to the type of a channel. Complementary metal oxide semiconductor (CMOS) transistors include an NMOS transistor and a PMOS transistor that are formed on one substrate.

When the NMOS transistor and the PMOS transistor are formed, different types of ions are implanted into polysilicon gates of the NMOS transistor and the PMOS transistor. For this reason, the resistance and work function of the gate of the NMOS transistor may be different from those of the PMOS transistor gate.

Accordingly, the performance of semiconductor devices including CMOS transistors may be degraded or less than optimal.

### SUMMARY

Embodiments of the invention provide a semiconductor device capable of reducing a difference in characteristics of gate electrodes in order to improve the performance of the semiconductor device.

According to one embodiment, a semiconductor device includes a semiconductor substrate having first and second active areas defined thereon by isolation layers, a first gate electrode in the first active area, in which the first gate electrode includes a first silicide having a first composition ratio, and a second gate electrode in the second active area, in which the second gate electrode includes a second silicide having a second composition ratio different from the first composition ratio.

According to another embodiment, a method of fabricating a semiconductor device includes the steps of forming isolation layers defining first and second active areas on a semiconductor substrate, forming a first gate electrode including a first silicide in the first active area, the first gate electrode having a first composition ratio, and forming a second gate electrode in the second active area, in which the second gate electrode includes a second silicide having a second composition ratio different from the first composition ratio.

According to yet another embodiment, a semiconductor device includes a semiconductor substrate having first and second active areas defined thereon, a first gate electrode in the first area, in which the first gate electrode includes a first metal silicide having a first composition ratio, a second gate electrode in the second area, in which the second gate electrode includes a second metal silicide having a second composition ratio different from the first composition ratio, a first source/drain area at a side of the first gate electrode, and a second source/drain area at aside of the second gate electrode.

The gate electrodes of the semiconductor device include different types of silicide having different composition ratios (e.g., of silicon and/or metal, such as in a silicon/metal ratio). Accordingly, the characteristic difference between the gate electrodes derived from implanted ions can be compensated by adjusting a silicon-to-metal ratio in the silicides of the gate electrodes. Accordingly, the characteristic difference(s) between the gate electrodes in NMOS and PMOS transistors can be reduced.

### BRIEF DESCRIPTION OF THE DRAWINGS

FIG. 1 is a sectional view showing a CMOS transistor pair; and

FIGS. 2A to 2F are sectional views showing the manufacturing process according to a method of fabricating CMOS transistors.

### DETAILED DESCRIPTION OF THE EMBODIMENTS

CMOS Transistors

FIG. 1 is a sectional view showing a CMOS transistor pair.

Referring to FIG. 1, the CMOS transistor pair includes a semiconductor substrate 100, an isolation layer 200, an NMOS transistor 300, and a PMOS transistor 400.

The semiconductor substrate 100 includes a P-well 110 having P-type impurities and an N-well having N-type impurities. Suitable P-type impurities include boron (B) and gallium (Ga), and suitable N-type impurities include phosphorous (P), arsenic (As), and antimony (Sb). In addition, first and second active areas AR1 and AR2 are defined (e.g., separated and/or bordered) by the isolation layer 200 on the semiconductor substrate 100.

The first active area AR1 is formed in the P-well 110. In other words, the first active area AR1 includes P-type impurities, and the second active area AR2 includes N-type impurities.

The isolation layer 200 is disposed inside a shallow trench isolation (STI) structure formed on the semiconductor substrate 100. Alternatively or additionally, the isolation layer 200 may comprise a field oxide formed by local oxidation of silicon (LOCOS). The isolation layer 200 is an insulator. For example, the isolation layer 200 may be an oxide layer, but it may have one or more thin insulator layers (e.g., thermal oxide, silicon nitride) liner and/or pad layers thereunder. The isolation layer 200 helps to isolate the PMOS transistor 400 from the NMOS transistor 300.

The NMOS transistor 300 is formed in the first active area AR1. The NMOS transistor 300 includes a first gate insulating layer 310, a first gate electrode 320, first gate spacers 330, first LDD areas 340, first source/drain areas 350, and first silicide layers 360. Generally, the LDD areas 340 are aligned with the gate 320, and the source/drain areas 350 are aligned with the spacers 330.

The first gate insulating layer 310 is formed or disposed in the first active area AR1 on the semiconductor substrate 100. The gate insulating layer 310 may include a silicon oxide SiOx (e.g., where x=2), such as a thermal oxide.

The first gate electrode 320 is on the first gate insulating layer 310, and includes a first silicide. The first silicide may include first nickel silicide (NiₓSi_{y}), cobalt silicide (CoₓSi_{y}), palladium silicide (PdₓSi_{y}), tungsten silicide (WₓSi_{y}), molybdenum silicide (MoₓSi_{y}), tantalum silicide (TaₓSi_{y}), or titanium silicide (TiₓSi_{y}). The first gate electrode 320 may also include germanium (Ge), and thus, the gate 320 may include a metal germanide (MₓGe_{y}) or germasilicide (MₓSi_{y}Ge_{z}). In one implementation, the whole gate electrode 320 includes the first silicide. In other words, the first gate electrode 320 may consist essentially of the first silicide.

The first gate spacers 330 are disposed at side surfaces of the first gate electrode 320 on the semiconductor substrate 100. The first gate spacers 330 insulate the side surfaces of the first gate electrode 320. The first gate spacer 330 may include one or more insulator layers, such as silicon dioxide and/or silicon nitride. The gate spacers 340 may also comprise a multilayer structure, such as silicon dioxide on silicon nitride, silicon nitride on silicon dioxide, or a silicon dioxide/silicon nitride/silicon dioxide stack.

The first LDD area(s) 340 are under the first gate spacer 330. The first LDD area 340 is formed by implanting N-type impurities at a light dose or doping level into the semiconductor substrate 100, using the gate 320 (but not spacers 330) as a mask.

The first source/drain area 350 is formed in the substrate at the side of the first gate spacers 330. The first source/drain area 350 is formed by implanting N-type impurities at a high dose or doping level into the semiconductor substrate 100.

The first silicide layer 360 is formed on the first source/drain area 350, and includes a second silicide. For example, the second silicide may include nickel silicide (NiₘSiₙ) or any of the other metal silicides described above, although at a second composition ratio (e.g., silicon-to-metal ratio) which may be the same as or different from the composition ratio of the gate 320.

The PMOS transistor 400 is formed in the second active area AR2. The PMOS transistor 400 includes a second gate insulating layer 410, a second gate electrode 420, gate spacers 430, second LDD areas 440, second source/drain areas 450, and second silicide layers 460.

The second gate insulating layer 410 is formed or disposed in the second active area AR2 defined on the semiconductor substrate 100. The second gate insulating layer 410 includes a silicon oxide, such as a thermal oxide.

The second gate electrode 420 is disposed on the second gate insulating layer 410, and includes third silicide. The third silicide has a composition ratio different from that of the first silicide. The third silicide may include a third nickel silicide (Ni_{w}Si_{z}) or any of the other metal silicides described above, although at a second composition ratio (e.g., silicon-to-metal ratio) which may be the same as or different from the composition ratio of either or both of the silicide layers 360 and/or 460.

For example, the third silicide may have a higher composition ratio of metal to silicon, and a lower composition ratio of silicon to metal, as compared with the first silicide. The difference in the composition ratios may be at least 0.05, 0.1, 0.15, 0.2 or any value greater than 0.05, optionally up to about 0.3, 0.4, 0.5, 0.6 or 0.8. For example, the third silicide may have a composition ratio of silicon to metal of 2.0:1, whereas the first silicide may have a composition ratio of silicon to metal of 2.1:1, 2.2:1, or other value depending on the thickness(es) of the gates 320 and 420 and/or the dopant doses in the gates 320 and 420, the channels of transistors 300 and 400, the source/drain terminals 350 and 450, and/or the LDDs 340 and 440.

In addition, the whole second gate electrode 420 may include the third silicide. In other words, the second gate electrode 420 may consist essentially of the third silicide.

The second gate spacers 430 are disposed at side surfaces of the second gate electrode 420 on the semiconductor substrate 100. The second gate spacers 430 insulate the side surfaces of the second gate electrode 420. The second gate spacer 430 may include nitride and/or a tetraethylorthosilicate (TEOS)-based silicon oxide, similar to spacers 330.

The second LDD area(s) 440 are under the second gate spacer(s) 430. The second LDD area 440 is formed by implanting P-type impurities at a light dose or doping level into the semiconductor substrate 100.

The second source/drain area(s) 450 are formed at opposite sides of the second gate spacers 430. The second source/drain area 450 is formed by implanting P-type impurities at a high dose or doping level into the semiconductor substrate 100.

A fourth silicide layer 460 is formed on the second source/drain area 450. The fourth silicide layer 460 may have the same material (e.g., nickel silicide) and composition ratio as that of the third silicide layer 360.

The first gate electrode 320 is implanted with N-type impurities for manufacturing the NMOS transistor 300, and the second gate electrode 420 is implanted with N-type impurities for manufacturing the PMOS transistor 400.

The characteristic difference between the first and second gate electrodes 320 and 420 derived from implanted impurities can be compensated by adjusting a silicon-to-metal ratio in the silicide in each of the first and second gate electrodes 320 and 420.

Accordingly, a resistance difference between the first and second gate electrodes 320 and 420 can be reduced, and the performance of a semiconductor device can be performed.

Method of Fabricating CMOS Transistor

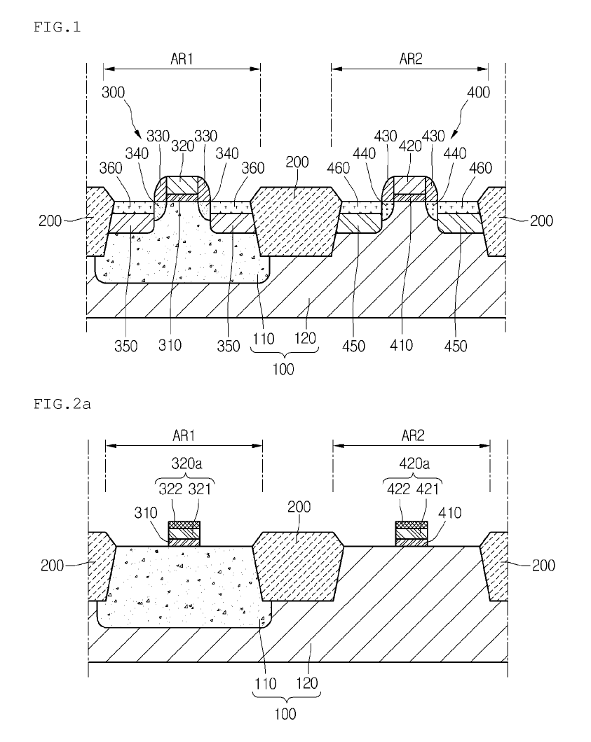

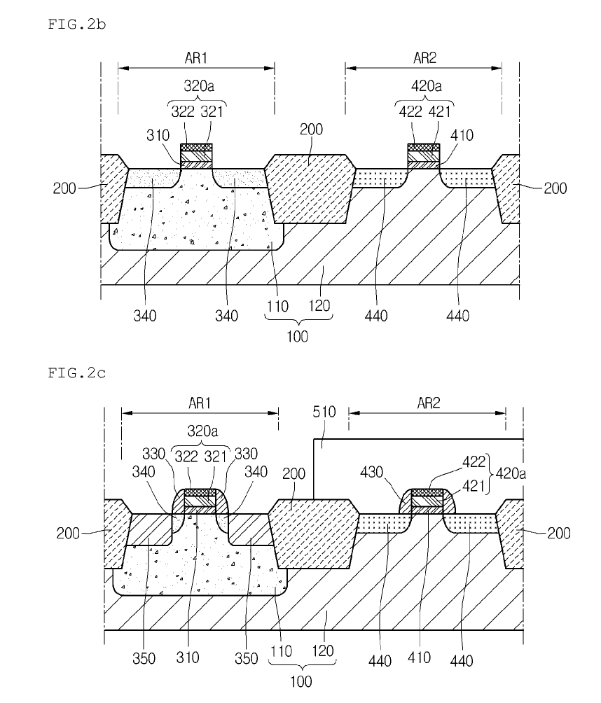

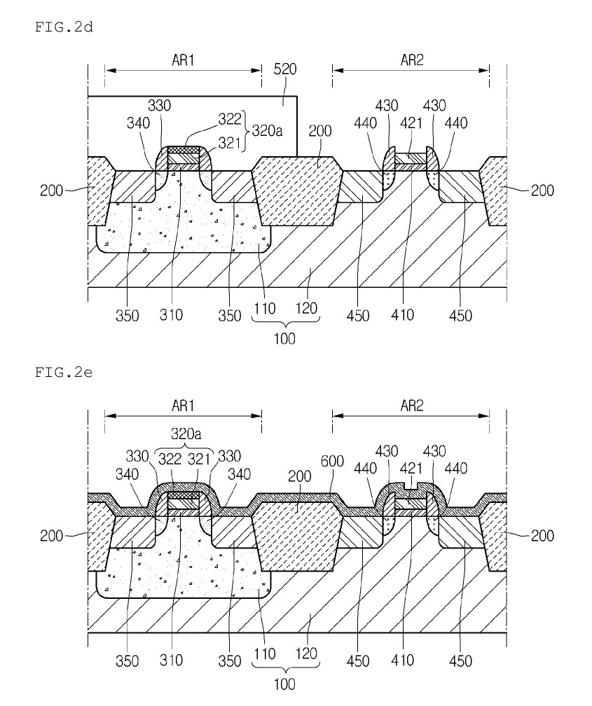

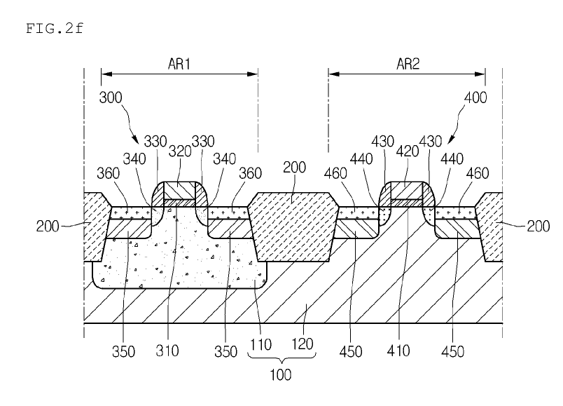

FIGS. 2A to 2F are sectional views showing the manufacturing process according a method for manufacturing a CMOS transistor pair.

Referring to FIG. 2A, after forming a trench in an N-type semiconductor substrate 120, an oxide layer is formed inside the trench, thereby forming an isolation layer 200. The oxide layer may comprise a TEOS-based oxide, or a gap-fill oxide such as a plasma silane (p-SiH₄), which forms silicon dioxide upon exposure and/or reaction with an oxygen source such as O₂ and/or O₃. A first active area AR1 and a second active area AR2 are defined on the N-type semiconductor substrate 120 by the isolation layer 200.

Thereafter, a light dose of P-type impurities are selectively implanted into the first active area AR1, thereby forming a P-well 110.

The semiconductor substrate 100 with the P-well 110 is thermally oxidized, thereby forming an oxide layer on the semiconductor substrate 100. After the oxide layer is formed, polysilicon is deposited on the oxide layer, thereby forming a polysilicon layer. The polysilicon layer may be formed using a chemical vapor deposition (CVD) process.

A germanium-silicon epitaxial layer may then be grown on the polysilicon layer. In detail, the germanium-silicon epitaxial layer can be grown by applying a reaction gas including germanium (e.g., GeH₄) and silicon (e.g., SiH₄) onto the semiconductor substrate 100 with the oxide layer thereon.

The oxide layer, the polysilicon layer, and the epitaxial layer are patterned through a mask process, and a first gate insulating layer 310, a second gate insulating layer 410, a first preliminary gate electrode 320a (including silicon layer 321 and SiGe epitaxial layer 322), and a second preliminary gate electrode 420a (including silicon layer 421 and SiGe epitaxial layer 422) are formed on the semiconductor substrate 100.

Referring to FIG. 2B, a light dose of N-type impurities are implanted into the first active area AR1 by using the first preliminary gate electrode 320a as a mask, thereby forming first lightly doped dopant (LDD) areas 340. In addition, a light dose of P-type impurities are implanted into the second active area AR2 by using the second preliminary gate electrode 420a as a mask, thereby forming second LDD areas 440.

Referring to FIG. 2C, after the first and second LDD areas 340 and 440 are formed, a nitride layer is formed to cover the first and second preliminary gate electrodes 320a and 420a. An oxide layer may also be formed to cover the first and second preliminary gate electrodes 320a and 420a, before and/or after the nitride layer.

The nitride layer (and any oxide layer[s] that are present) is etched through an anisotropic etching process such as an etchback process, thereby forming first gate spacers 330 at the side surface of the first preliminary gate electrode 320a, and forming second gate spacers 430 at the side surfaces of the second gate electrode 420a.

Thereafter, a first photoresist pattern 510 is formed to cover the second active area AR2, and a high dose of N-type impurities are implanted into the first active area AR1 using the first preliminary gate electrode 320a and the first gate spacers 330 as a mask, thereby forming first source/drain areas 350.

Referring to FIG. 2D, after the first source/drain areas 350 are formed, the first photoresist pattern 510 covering the second active area AR2 is removed through an ashing process, and a second photoresist pattern 520 is formed to cover the first active area AR1.

After the second photoresist pattern 520 is formed, a high dose of P-type impurities are implanted into the second active area AR2 by using the second preliminary gate electrode 420a and the second gate spacers 430 as a mask, thereby forming second/drain areas 450.

The germanium-silicon epitaxial layer 422 of the second preliminary gate electrode 420a may then be etched by an etchant while the second photoresist pattern 520 is present. The etchant may include a mixture of an acid (e.g., a fluorinated acid such as hydrogen fluoride [HF] and an oxidizing acid such as nitric acid [HNO₃], or a mixture of sulfuric acid and hydrogen peroxide) and water (e.g., deionized water).

Referring to FIG. 2E, after the germanium-silicon epitaxial layer of the second preliminary gate electrode 420a is etched and/or removed, a metal layer 600 is formed to cover the first preliminary gate electrode 320a, the first source/drain area 350, the second preliminary gate electrode 420a, and the second source/drain area 450. The metal layer 600 may include nickel or any other silicide-forming metal, such as those described herein.

Referring to FIG. 2F, silicide is formed on or from the first and second preliminary gate electrodes 320a and 420a through a rapid thermal annealing (RTA) and on the semiconductor substrate 100 with the metal layer 600 thereon.

Thereafter, the unreacted metal layer is removed by a solution including hydrogen fluoride (HF) or other etchant that selectively removes elemental metal without removing the corresponding metal silicide, and a secondary RTA process is performed with respect to the resultant structure, thereby forming a first gate electrode 320, a first silicide layer 360, a second silicide layer 460, and a second gate electrode 420.

The first gate electrode 320 is formed on the first gate insulating layer 310, and includes a first silicide. For example, the first silicide may be nickel silicide (NiₓSi_{y}) or any other metal silicide disclosed herein.

The third silicide layer 360 is formed on the first source/drain area 350, and the fourth silicide layer 460 is formed on the second source/drain area 450. The third and fourth silicide layers 360 and 460 include a second silicide. For example, the second silicide may include a second nickel silicide (NiₘSiₙ).

The second gate electrode 420 is formed on the second gate insulating layer 410, and includes a third silicide. For example, the third silicide may be a third nickel silicide (Ni_{w}Si_{z}).

When comparing the first preliminary gate electrode 320a with the second preliminary gate electrode 420a in terms of the amount of silicon reacting with the metal layer 600, the first and second preliminary gate electrodes 320a and 420a have a difference in reactivity with the metal layer 600. Accordingly, the first silicide has a composition ratio (e.g., of silicon-to-metal) different from that of the third silicide.

The first gate electrode 320 is implanted with N-type impurities when the first LDD areas 340 and the first source/drain areas 350 are formed, and the second gate electrode 420 is implanted with P-type impurities when the second LDD areas 440 and the second source/drain areas 450 are formed.

Since different types of impurities are implanted into the first and second gate electrodes 320 and 420, a difference may be made between characteristics of the first and second gate electrodes 320 and 420. Such a characteristic difference can be compensated by reducing the composition ratio of silicon to metal in the third silicide.

In other words, the first gate electrode 320 may have resistance substantially identical to that of the second gate electrode 420.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate having first and second active areas defined thereon by isolation layers;
a first gate electrode in the first active area, in which the first gate electrode includes a first silicide having a first composition ratio; and
a second gate electrode in the second active area, in which the second gate electrode includes a second silicide having a second composition ratio different from the first composition ratio.

2. The semiconductor device of claim 1, wherein the first and second silicide each include nickel silicide.

3. The semiconductor device of claim 1, wherein the first composition ratio has a proportion of silicon that is higher than the second composition ratio.

4. The semiconductor device of claim 1, wherein at least one of the first and second gate electrodes includes germanium.

5. The semiconductor device of claim 1, wherein the first gate electrode includes a first type of conductive impurity, and the second gate electrode includes a second type of conductive impurity different from the first type of conductive impurity.

6. A method of fabricating a semiconductor device, the method comprising the steps of:
forming isolation layers defining first and second active areas on a semiconductor substrate;
forming a first gate electrode including a first silicide in the first active area, the first silicide having a first composition ratio; and
forming a second gate electrode in the second active area, in which the second gate electrode includes a second silicide having a composition ratio different from the first composition ratio.

7. The method of claim 6, further comprising implanting first impurities into the semiconductor substrate and implanting second impurities into the first active area.

8. The method of claim 6, wherein the step of forming the second gate electrode includes the steps of:
forming a preliminary gate electrode including silicon; and
removing a portion of the preliminary gate electrode.

9. The method of claim 6, wherein the step of forming the second gate electrode includes the steps of:
forming a preliminary gate electrode including a polysilicon layer and an epitaxial layer in the second active area;
removing the epitaxial layer; and
reacting the polysilicon layer with a metal.

10. The method of claim 9, wherein the step of reacting the polysilicon layer with the metal includes the steps of:
depositing the metal on the polysilicon layer; and
performing a primary rapid thermal annealing process on the polysilicon layer and the metal.

11. The method of claim 10, wherein the step of performing the primary rapid thermal annealing process is conducted at a temperature of from 400 to 450° C.

12. The method of claim 10, further comprising, after the primary rapid thermal annealing process, performing a secondary rapid thermal annealing process on the polysilicon layer at a temperature in of from 450 to 480° C.

13. The method of claim 9, wherein removing the epitaxial layer comprises etching with an etchant including hydrogen fluoride, nitric acid, and water.

14. A semiconductor device comprising:
a semiconductor substrate having first and second active areas defined thereon;
a first gate electrode in the first area, in which the first gate electrode includes a first metal silicide having a first composition ratio;
a second gate electrode in the second area, in which the second gate electrode includes a second metal silicide having a second composition ratio different from the first composition ratio;
a first source/drain area at a side of the first gate electrode; and
a second source/drain area at a side of the second gate electrode.

15. The semiconductor device of claim 14, wherein the first metal silicide and the second metal silicide each comprise nickel silicide.

16. The semiconductor device of claim 14, wherein the first metal silicide has a proportion of metal higher than the second metal silicide.

17. The semiconductor device of claim 16, wherein the second metal silicide has a proportion of silicon higher than the first metal silicide.

18. The semiconductor device of claim 14, wherein the first gate electrode consists essentially of the first metal silicide, and the second gate electrode consists essentially of the second metal silicide.

19. The semiconductor device of claim 14, wherein the first and second source/drain areas include a third metal silicide having a third composition ratio different from the first and second composition ratios.
